(19) United States
(12) Patent Application Publication
(10) Pub. No.: US 2005/0020072 A1
(43) Pub. Date: Jan. 27, 2005

(54) Means and method for patterning a substrate with a mask

(76) Inventors: Robert Kachel, Munchen (DE); Gerhard Franz, Munchen (DE)

Correspondence Address: BEVER HOFFMAN & HARMS, LLP;TRI-VALLEY OFFICE, 1432 CONCANNON BLVD., BLDG. G, LIVERMORE, CA, 94550, US

(21) Appl. No.: 10/489,632

(22) PCT Filed: Sep. 11, 2001
(86) PCT No.: PCT/DE01/03519

(51) Int. Cl. H01L 21/302; H01L 21/461

(52) U.S. Cl. 438/689

(57) ABSTRACT

A multilayer mask for patterning a platinum (or other) layer formed on a substrate. The multilayer mask includes a first dielectric layer formed on the platinum layer, a bottom resist layer formed over the first dielectric layer, a second dielectric layer formed on the bottom resist layer, and a top (structure) resist layer formed on the second dielectric layer. The second dielectric layer is patterned using the top resist layer, and serves to prevent photoresist rounding. The first dielectric layer prevents “micro-masking” by acting as an etch stop during subsequent patterning of the bottom resist layer, which is performed using dry etching techniques. The first dielectric layer is then wet etched to expose the platinum layer.

The invention relates to a means for patterning a substrate with a mask according to the preamble of claim 1 and a method according to the preamble of claim 5.

In the fabrication of structures for microelectronics, in many cases a substrate is processed by means of a dry etching in order to produce said structures. Typical dry etching methods are e.g. plasma etching, reactive ion etching or ion beam etching.

In these methods, a plasma acts on the substrate, e.g. a wafer, coated with an exposed photoresist (resist). In order that a structure is transferred exactly to the substrate, it is necessary, in order to achieve good etching results even at high DC voltage potentials in the plasma installation, that the edges of the photoresist are as far as possible perpendicular. If the order of magnitude of the structure to be etched is greater than the thickness of the photoresist, instances of photoresist rounding occur during the so-called post-bake step or at the latest during patterning owing to surface tension effects. This has the consequence that the material lying below the photoresist is etched laterally inaccurately during the patterning.

In order to avoid these structural inaccuracies, a so-called three-layer resist has been developed as a multilayer mask, in which a so-called bottom resist is applied to the substrate. Above that, the bottom resist is provided with a dielectric mask made of SiO₂ or Si₃N₄. Said mask may then be patterned e.g. in a CF₄/O₂ plasma. However, this requires a further photoresist layer to be applied to the dielectric layer

(called structure resist layer hereinafter). Consequently, the three-layer resist has a layering (from the top) comprising structure resist, SiO₂/Si₃N₄ mask layer, bottom resist. Perpendicular photoresist side walls of up to 7 μm have been produced using such a three-layer mask (see G. Franz, J. Vac. Sci. Technol. A16, 1542 (1998); G. Franz, F. Rinner; J. Vac. Sci. Technol. A17, 56 (1999)).

However, during the patterning of metal, in particular platinum, layers of a substrate, it has been found that, during the patterning of the bottom resist, the underlying metal (here platinum) may be sputtered away since the etching end point can be identified spectroscopically only when an incipient etching has already taken place, i.e. when platinum has already been sputtered away. As a result of the sputtering away, the platinum is distributed on the substrate, which is undesirable. A so-called “micro-masking” arises during the subsequent etching step in the semiconductor.

The present invention is based on the object of providing a means for patterning a substrate with a mask and a method for patterning a substrate with a mask in which an undesirable incipient etching and a sputtering away of material of the substrate are avoided.

This object is achieved according to the invention by a means having the features of claim 1.

The fact that a mask has at least one layer with or made of a wet-patternable dielectric which is resistant to a dry etching prevents an incipient etching of the substrate lying below the mask.

In this case, it is advantageous if the dielectric has at least one proportion of SiO₂, Si₃N₄, Al₂O₃, SiOₓN_{y} (silicon oxynitride) and/or TiO₂ or wholly comprises one of said

substances. Layers with or made of said substances can readily be deposited on substrates.

In this case, it is advantageous if the layer with or made of the dielectric has a thickness of 30 to 50 nm.

It is particularly advantageous if the layer with or made of the dielectric is arranged below a bottom resist of a three-layer resist since the latter can be used to produce particularly good side walls in a photoresist.

The object is also achieved by a method having the features of claim 5.

By applying at least one layer of the mask made of a wet-patternable dielectric which is resistant to dry etching. In this case, the layer may have a dielectric or comprise it. An etching stop for the underlying substrate is thus realized in an efficient manner.

The layer made of or with the dielectric is advantageously applied to the substrate before the application of a bottom resist layer of a three-layer resist.

It is also advantageous if, after the patterning of the bottom resist by means of a dry etching method, in particular an RIE method, the layer made of or with the dielectric is etched wet-chemically.

Particularly efficient wet-chemical etchants for the dielectric are phosphoric acid (H₂PO₄) for sputtered Al₂O₃, hydrofluoric acid (HF) or ammonium-buffered HF (HF/NH₄F) for Si-containing dielectrics. In this case, it is advantageous if the phosphoric acid is diluted with water in the ratio 1:1 and has a temperature of 70° C.

In a further advantageous refinement of the method according to the invention the layer made of or with the dielectric is used as an etching stop, in particular in an automated method.

The invention is explained in more detail below using a plurality of exemplary embodiments with reference to the figures of the drawings, in which:

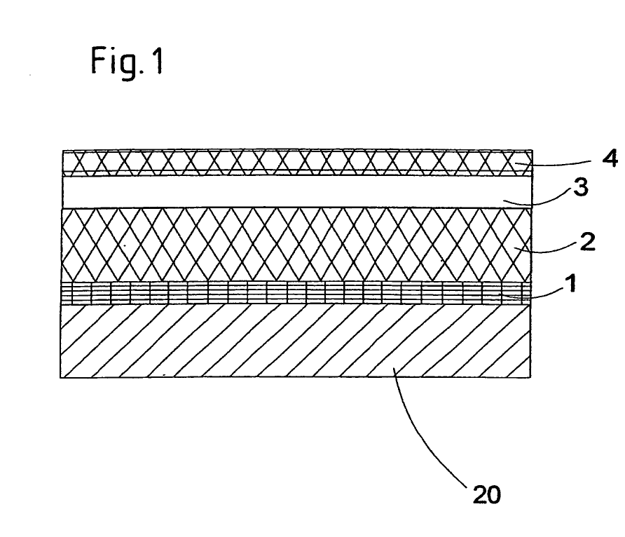

FIG. 1 shows a diagrammatic sectional view of a substrate with an embodiment of the patterning means according to the invention;

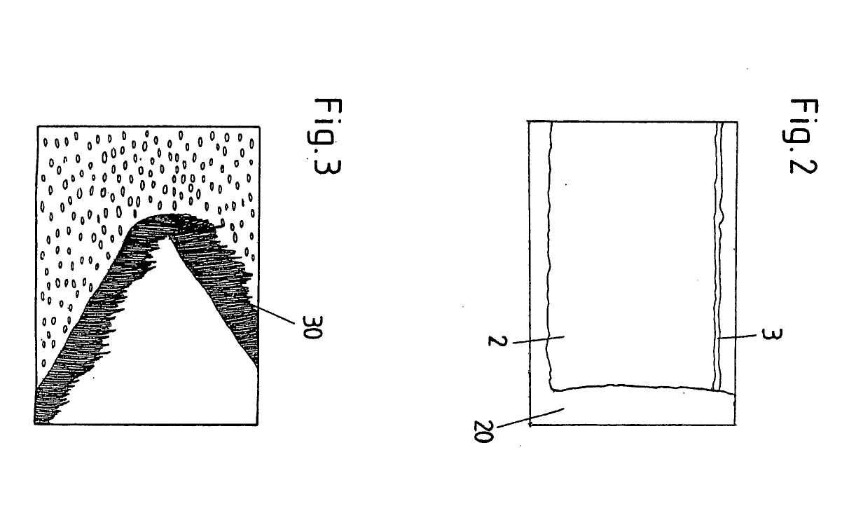

FIG. 2 shows a patterning result with a known three-layer resist;

FIG. 3 shows a patterning result with a known three-layer resist after the removal of the resist;

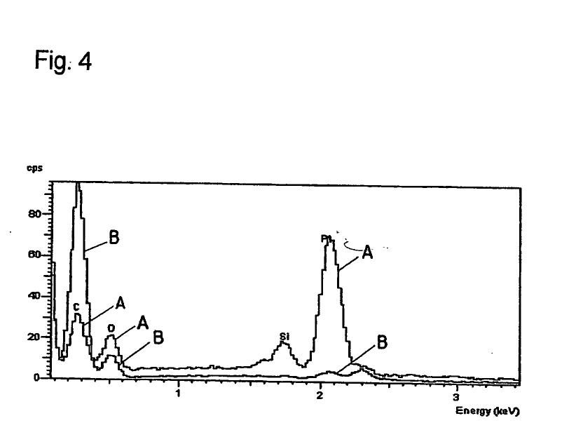

FIG. 4 shows an EDX spectrum for a structure fabricated by a known method and a structure fabricated by the method according to the invention.

FIG. 1, which is diagrammatic and not to scale, illustrates a section through a configuration of the invention's means for patterning a substrate 20. The substrate 20 in this case is a semiconductor material (e.g. silicon or a III-V semiconductor) with a platinum layer. The inventive means and the inventive methods are suitable precisely for the III-V semiconductors used in the field of optoelectronics.

The patterning means in this case is a multilayer mask 1, 2, 3, 4. Since said masks 1, 2, 3, 4 is constructed from four layers, it is also called quadro-level layer.

According to the invention, a layer 1 made of a wet-chemically patternable dielectric is arranged on the substrate 20, the dielectric chosen being resistant to dry etching methods for the photoresist of an overlying layer.

Such a dielectric layer 1 may for example comprise SiO₂, Si₃N₄, SiOₓN_{y}, Al₂O₃ and/or TiO₂ or have proportions of said substances.

It is this dielectric layer 1 which prevents the substrate 20 from being incipiently etched during a patterning of overlying layers 2, 3, 4; it acts as an etching stop. Any etching which uses e.g. a noble metal (e.g. Au, Ag, Pt) or a refractory metal (e.g. Co, Mo, W, Ti on semiconductor) as an etching stop has the disadvantage that removed material of this layer is deposited in direct proximity with the formation of “micromasking”. This is very disturbing for the subsequent etching. The layer 1 made of or with a dielectric which can be removed wet-chemically avoids this undesirable effect.

The invention's method for fabricating the patterning means provides for said dielectric layer to be applied before the application of another layer of the multilayer mask layer.

This means according to the invention and the corresponding methods for fabricating this means are suitable for setting the end point of an etching very accurately (to the nanometer). In known methods, the end point of an etching can only be determined inaccurately, since, in order to detect the end point, it must be possible to detect the underlying material in the plasma, i.e. a removal must already have taken place. Although the dielectric is also removed weakly, it can be removed quantitatively during the subsequent wet etching.

The negative consequences of an undesirable removal are illustrated in FIG. 3.

In FIG. 1, a three-layer resist mask 2, 3, 4 known per se is arranged above the dielectric layer 1.

A bottom resist 2 having a relatively high layer thickness (e.g. a number of micrometers) is patterned by means of a dry etching method, as mentioned. A mask layer 3 made of SiO₂ or Si₃N₄ is provided for this. A structure resist layer 4 in turn serves for the patterning of the mask layer 3.

FIG. 2 shows a tracing of an SEM recording of such a three-layer resist layering known per se. The substrate 20 in this case has a platinum layer, on which a bottom resist 2 layer having a thickness of approx. 7.3 μm is arranged. Arranged above the bottom resist 2 is a very thin covering layer made of Si₃N₄ as mask layer 3.

FIG. 3 shows a tracing of an SEM recording illustrating the structure illustrated in FIG. 2 after the dry etching.

During the dry etching with oxygen, the thin platinum coating of the substrate 20 is incipiently sputtered, so that said platinum deposits at the side walls of the three-layer mask 2, 3, 4. After the removal of the mask 2, 3, 4, this sputtered-away platinum remains as a kind of “fence” 30.

In this case, not inconsiderable quantities of platinum may be sputtered away, since customary mask spectrometers cannot detect platinum well on account of its high atomic weight. Moreover, platinum is not adequately converted into volatile compounds for detection by other methods. All this makes it difficult to detect an etching end point.

During the deposition (redeposition) of the material (here platinum), although a contiguous layer is not formed, point masks are indeed formed thereby and lead to a “needle or grass formation” during a subsequent etching step.

In this case, the example of a platinum layer on a substrate is used to illustrate how, during a reactive etching process (in this case etching with oxygen), the uncovered material forms an etching stop since it has no chemical affinity whatsoever with the etching gas. However, the material is removed by physical sputtering and deposited again.

In order to prevent that, the wet-chemically patternable dielectric layer 1 resistant to dry etching is inserted as an additional etching stop layer. This layer 1 can be removed wet-chemically. As a result, the means according to the invention and the method according to the invention can be used for any type of patterning with an etching stop but also with end point detection (accuracy not better than 1 nm). A redeposition is avoided.

FIG. 4 shows an EDX spectrum (Energy Dispersive X-Ray Analysis) illustrating the signals of a patterning with a three-level resist (curve A) and a quadro-level mask according to the invention (curve B). The platinum peak of curve A shows (identified by Pt) that platinum is present in the case of a three-layer mask without a dielectric layer 1 according to the invention. With the use of the quadro-level technique according to the invention, i.e. with a dielectric layer 1, no appreciable instances of platinum being sputtered away can be detected; no incipient etching of the platinum layer on the substrate 20 has taken place.

As a result, the dielectric layer 1 according to the invention may also be used for an automatic regulation of the fabrication process. As soon as portions of the dielectric layer

can be detected, the etching step is stopped. In a subsequent wet etching, the traces of the dielectric are then removed.

The embodiment of the invention is not restricted to the preferred exemplary embodiments specified above. Rather, a number of variants are conceivable which make use of the means according to the invention and the method according to the invention also in the case of embodiments of fundamentally different configuration.

List of Reference Symbols

1 Layer made of wet-patternable dielectric
2 Bottom resist
3 Mask layer
4 Structure resist layer
20 Substrate
30 Fence made of sputtered-away platinum

1. A means for patterning a substrate with a mask, the mask having at least one layer with or made of a wet-patternable dielectric which is resistant to a dry etching,
characterized
in that the layer (1) with or made of the dielectric is arranged below a bottom resist (2) of a three-layer resist (2, 3, 4).

2. The means as claimed in claim 1, characterized in that the dielectric has at least one proportion of SiO₂, Si₃N₄, SiOₓN_{y}, Al₂O₃ and/or TiO₂ or wholly comprises one of said substances.

3. The means as claimed in claim 1 or 2, characterized in that the layer (1) with or made of the dielectric has a thickness of 30 to 50 nm.

4. A method for patterning a substrate using a mask, at least one layer of the multilayer mask having or comprising a wet-patternable dielectric which is resistant to dry etching,
characterized
in that the layer (1) with or made of the dielectric is applied to the substrate (20) before the application of a bottom resist (2) layer of a three-layer resist (2, 3, 4).

5. The method as claimed in claim 4, characterized in that, after the patterning of the bottom resist (2) by means of a dry etching method, in particular an RIE method, the layer (1) with or made of the dielectric is etched wet-chemically.

6. The method as claimed in claim 5, characterized in that the wet-chemical etching of the layer (1) made of or with a dielectric is effected using phosphoric acid (H₂PO₃), hydrofluoric acid (HF) or ammonium-buffered HF (HF/NH₄F).

7. The method as claimed in claim 6, characterized in that the phosphoric acid is diluted with water in the ratio 1:1 and has a temperature of 70° C.

8. The method as claimed in at least one of claims 4 to 7, characterized in that the layer (1) made of or with a dielectric is used as an etching stop, in particular in an automated method.
